(19) United States
(12) Patent Application Publication
(10) Pub. No.: US 2016/0267999 A1
(43) Pub. Date: Sep. 15, 2016

(54) SEMICONDUCTOR MEMORY DEVICE AND MEMORY SYSTEM

(71) Applicant: Kabushiki Kaisha Toshiba, Minato-ku (JP)

(72) Inventors: Yoshikazu TAKEYAMA, Fujisawa (JP); Yuji Nagai, Sagamihara (JP); Katsuaki Isobe, Yokohama (JP)

(73) Assignee: Kabushiki Kaisha Toshiba, Minato-ku (JP)

(21) Appl. No.: 14/847,569

(22) Filed: Sep. 8, 2015

Related U.S. Application Data
(60) Provisional application No. 62/132,144, filed on Mar. 12, 2015.

(51) Int. Cl. G11C 16/28

(52) U.S. Cl. CPC G11C 16/28

(57) ABSTRACT

According to one embodiment, a semiconductor memory device includes: memory cells; word lines electrically connected to gates of the memory cell; and an interconnect electrically connected to one end of the memory cells. A first potential for applying to a selected memory cell in a read operation is determined based on a potential of the interconnect during sequentially increasing or decreasing a potential of the word line.

### CROSS-REFERENCE TO RELATED APPLICATIONS

This application claims the benefit of U.S. Provisional Application No. 62/132,144, filed Mar. 12, 2015, the entire contents of which are incorporated herein by reference.

### FIELD

Embodiments described herein relate generally to a semiconductor memory device and a memory system.

### BACKGROUND

NAND flash memories are known as semiconductor memory devices.

### BRIEF DESCRIPTION OF THE DRAWINGS

FIG. 1 is a block diagram of a memory system including a semiconductor memory device according to a first embodiment;

FIG. 2 is a configuration view of the semiconductor memory device according to the first embodiment;

FIG. 3 is a view illustrating the threshold distribution of memory cell transistors in the semiconductor memory device according to the first embodiment;

FIG. 4 is a view for use in explaining the reading operation of the semiconductor memory device according to the first embodiment;

FIG. 5 is a view illustrating a variation in a cell current (cell monitor electric potential) in the semiconductor memory device according to the first embodiment in a first operation, with the increase in the voltage of a word line;

FIG. 6 is a view illustrating electric potentials of a word line for the threshold distribution of the memory cell transistors in the first operation of FIG. 5;

FIG. 7 is a configuration view of a semiconductor memory device according to a second embodiment;

FIG. 8 is a view for use in explaining, by using an inflection point, a variation in a cell current (monitored cell electric potential) in a semiconductor memory device according to a third embodiment in a first operation, with the increase in a voltage of a word line;

FIG. 9 is a flowchart of a reading operation including a first operation of a semiconductor memory device in a fourth embodiment;

FIG. 10 is another flowchart of the reading operation including the first operation of the semiconductor memory device in the fourth embodiment;

FIG. 11 is a view illustrating the threshold distribution of a memory cell transistor in a semiconductor memory device according to a fifth embodiment, with regard to soft bit read.

FIG. 12 is a flowchart of a reading operation including a first operation of a semiconductor memory device in a fifth embodiment;

FIG. 13 is another flowchart of the reading operation including the first operation of the semiconductor memory device in the fifth embodiment;

FIG. 14 is a view illustrating a variation in a cell current (cell monitor electric potential) in a semiconductor memory device according to a sixth embodiment in a first operation, with the decrease in the voltage of a word line;

FIG. 15 is a view for use in explaining a reading operation including lockout and a first operation of a semiconductor memory device according to a seventh embodiment;

FIG. 16 is a view illustrating the cell currents (monitored cell electric potentials) in a case (a) that the lockout is not included and in a case (b) that the lockout is included in the first operation in the semiconductor memory device according to the seventh embodiment;

FIG. 17 is a view for use in explaining a reading operation including lockout and a first operation of a semiconductor memory device according to an eighth embodiment; and

FIG. 18 is a configuration view of a semiconductor memory device according to a ninth embodiment.

### DETAILED DESCRIPTION

In general, according to one embodiment, a semiconductor memory device includes: memory cells; word lines electrically connected to gates of the memory cells; and an interconnect electrically connected to one end of the memory cells. A first potential for applying to a selected memory cell in a read operation is determined based on a potential of the interconnect during sequentially increasing or decreasing a potential of the word line.

Some embodiments will be described below with reference to the accompanying drawings. Regarding the description, the same reference characters are given to identical parts in all the drawings.

### [1] First Embodiment

### [1-1] Configuration of Memory System

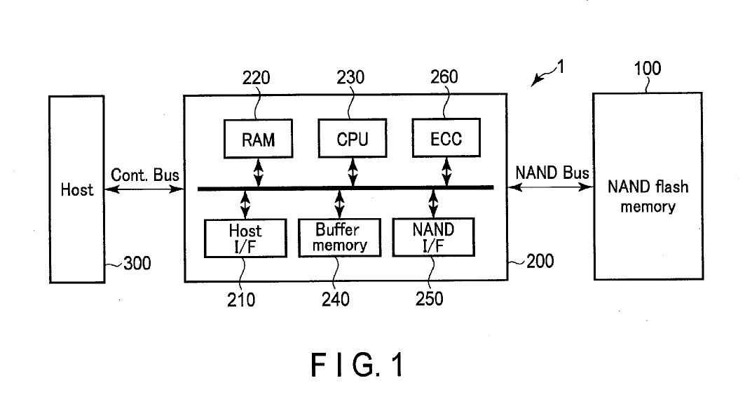

A description will be given of a configuration of a memory system including a semiconductor memory device according to a first embodiment, with reference to FIG. 1. The semiconductor memory device according to this embodiment will be embodied by a NAND flash memory.

As illustrated in FIG. 1, a memory system 1 includes a NAND flash memory 100, a controller 200 and a host apparatus 300.

The NAND flash memory 100 includes a plurality of memory cells and stores data in a nonvolatile manner. A description will be given later of details of the configuration of the NAND flash memory 100.

The controller 200 directs the NAND flash memory 100 to perform reading, writing, erasing, and other operations in response to instructions from the host apparatus 300. The controller 200 manages memory spaces in the NAND flash memory 100. For example, both the controller 200 and the NAND flash memory 100 may configure the same semiconductor device. Alternatively, the memory system 1 may be implemented using a single device, an example of which is a memory card, such as an SD™ card, or a solid state drive (SSD). The memory system 1 may be configured so that the NAND flash memory 100 and the controller 200 are built in a personal computer and may employ any non-limiting application equipped with the NAND flash memory 100.

The controller 200 includes a host interface circuit 210, a built-in memory (RAM) 220, a processor (CPU) 230, a buffer memory 240, a NAND interface circuit 250, and an ECC circuit 260.

The host interface circuit 210 is connected to the host apparatus 300 via a controller bus and is responsible for communicating with the host apparatus 300. The host interface circuit 210 forwards instructions and data received from the host apparatus 300 to both the CPU 230 and the buffer memory 240. In addition, the host interface circuit 210 forwards data within the buffer memory 240 to the host apparatus 300 in response to instructions from the CPU 230.

The NAND interface circuit 250 is connected to the NAND flash memory 100 via a NAND bus and is responsible for communicating with the NAND flash memory 100. The NAND interface circuit 250 transfers instructions received from the CPU 230 to the NAND flash memory 100 and transfers write data in the buffer memory 240 to the NAND flash memory 100 during a writing operation. During a reading operation, the NAND interface circuit 250 transfers read data from the NAND flash memory 100 to the buffer memory 240.

The CPU 230 controls the operation of the entire controller 200. For example, when the CPU 230 receives a write instruction from the host apparatus 300, it issues a write instruction based on a NAND interface in response to the instruction. The CPU 230 performs the reading and erasing operations in the same manner. Furthermore, the CPU 230 performs various processes of managing the NAND flash memory 100, such as wear levelling. The CPU 230 performs various calculations. For example, the CPU 230 performs a process of encrypting and randomizing data.

The ECC circuit 260 subjects data to an error checking and correcting (ECC) process. More specifically, the ECC circuit 260 generates parity based on write data during a data writing operation. During a reading operation, the ECC circuit 260 detects errors by generating syndromes from the parity and corrects the errors. It should be noted that the function of the ECC circuit 260 may be incorporated into the CPU 230.

The built-in memory 220 may be, for example, a semiconductor memory, such as a DRAM and is used as a working area for the CPU 230. The built-in memory 220 retains, for example, firmware for use in managing the NAND flash memory 100 and various management tables. The built-in memory 220 according to this embodiment may also retain information regarding a first read voltage determined from a first operation that will be described later.

### [1-2] Configuration of NAND Flash Memory

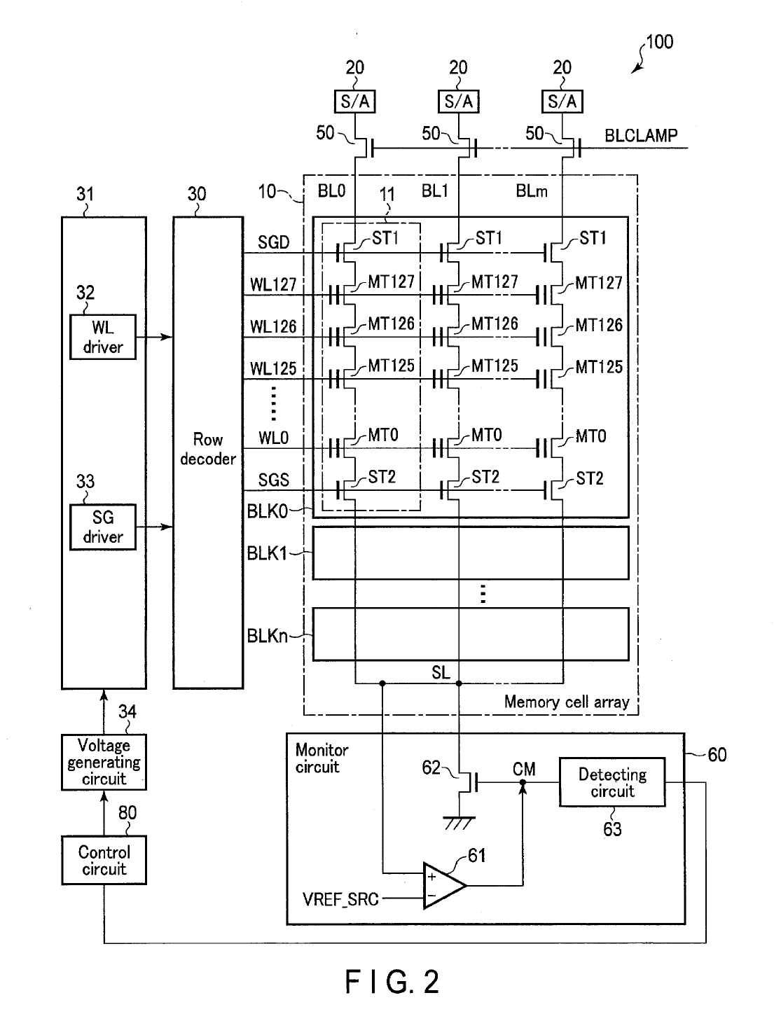

A description will be given of a configuration of the NAND flash memory according to the first embodiment with reference to FIG. 2.

As illustrated in FIG. 2, the NAND flash memory 100 includes a memory cell array 10, sense amplifiers 20, a row decoder 30, a driver circuit 31, a voltage generating circuit 34, MOS transistors 50, a monitor circuit 60, and a control circuit 80.

The memory cell array 10 includes a plurality of blocks BLK (BLK0 to BLKn (n: natural integer)). Each block BLK includes a plurality of NAND strings 11. Each NAND string includes, for example, 128 memory cell transistors MT (MT0 to MT127) and selection transistors ST1 and ST2.

Each memory cell transistor MT has a stacked gate structure including a charge storage layer and a control gate and retains data in a nonvolatile manner. The memory cell transistors MT may also be referred to as memory cells. The current paths of a plurality of memory cell transistors MT are connected in series between selection transistors ST1 and ST2. The drain of one end of the memory cell transistor MT in the series connection is connected to the source of the selection transistor ST1; the source of the other end of the memory cell transistor MT in the series connection is connected to the drain of the selection transistor ST2.

The control gates of memory cell transistors MT arrayed in the same row make a common connection with one of a plurality of word lines WL (WL0 to WL127). The gates of selection transistors ST1 and ST2 arrayed in the same row make a common connection with a select gate line SGD and SGS, respectively. Each of the drains of the selection transistors ST1 is connected to one of a plurality of bit lines BL (BL0 to BLm (m: natural integer)). The sources of the selection transistors ST2 make a common connection with a source line SL.

In a data reading operation, each of the sense amplifier 20 senses data that have been read from the memory cell transistors MT to the bit lines BL. In a data writing operation, each of the sense amplifiers 20 forwards writ data to corresponding bit lines BL.

In data writing, reading, and erasing operations, the row decoder 30 decodes block and page addresses, and applies a voltage to the select gate lines SGD and SGS and word lines WL of corresponding blocks BLK.

The driver circuit 31 supplies a voltage required to write, read, or erase data to the row decoder 30. The driver circuit 31 includes a word line driver 32 and a select gate line driver 33. The word line driver 32 applies a required voltage to the word lines WL through the row decoder 30. The select gate line driver 33 applies a required voltage to the select gate lines SGD and SGS through the row decoder 30.

The voltage generating circuit 34 generates a voltage required to write, read, or erase data and supplies this voltage to the driver circuit 31.

The each MOS transistor 50 includes a current path and gate. One end (first terminal) of the current path is connected to the corresponding bit lines BL and the other end (second terminal) of the current path is connected to the corresponding sense amplifiers 20. When a MOS transistor 50 is turned on, the bit line BL is electrically connected to the sense amplifier 20.

The monitor circuit 60 includes a detecting circuit 63 and a feedback circuit having a comparator 61 and a MOS transistor 62.

The comparator 61 includes a non-inverting input terminal (+) and an inverting input terminal (−). The non-inverting input terminal (+) of the comparator 61 is connected to the source line SL and a referential electric potential VREF_SRC enters to the inverting input terminal (−) of the comparator 61. The comparator 61 compares the electric potential of the source line SL with the referential electric potential VREF_SRC. Then, both the comparator 61 and the MOS transistor 62 operate in such a way that the electric potential of the source line SL becomes equal to the referential electric potential VREF_SRC.

The MOS transistor 62 includes a current path and a gate. One end of the current path of the MOS transistor 62 is connected to the source line SL and the other end of the current path of the MOS transistor 62 is connected to the ground terminal. An electric potential based on the comparison result of the comparator 61 is applied to the gate (cell monitor CM) of this MOS transistor 62.

The detecting circuit 63 is connected to the gate of the MOS transistor 62. If the difference (V2−V1) between the voltage V1 of a cell monitor CM at a first time t1 and the voltage V2 of the cell monitor CM at a second time t2 (t2>t1) becomes substantially 0 in a first operation that will be described later, the detecting circuit 63 determines that the voltages V1 and V2 of the cell monitor CM at the times t1 and t2, respectively, are substantially constant, the detecting circuit 63 transmits information regarding the times t1 and t2 to the control circuit 80. The information regarding the times t1 and t2 may be, for example, the number of clock signals or a time count value, which will be described later.

The control circuit 80 controls the operations of the entire NAND flash memory 100. According to this embodiment, in a first operation that will be described later, the control circuit 80 determines that the voltage applied to the word line WL at the times t1 and t2 is set as the read voltage (first read voltage) of the memory cell transistors MT, based on the information regarding the times t1 and t2 transmitted from the detecting circuit 63.

Data is simultaneously read from or written into a plurality of memory cell transistors MT which have a common connection with any of the word lines WL in any of the NAND strings 11 in any of the blocks BLK within the memory cell array 10. This unit is referred to as a “page”. Data is erased, for example, in the units of the blocks BLK, and data in the memory cell transistors MT within the same block BLK is erased simultaneously. However, data does not necessarily have to be erased in block units; for example, data may be erased in the units of halves of blocks. An exemplary method of erasing in units smaller than a block is described in U.S. patent Ser. No. 13/235,389 entitled “NONVOLATILE SEMICONDUCTOR MEMORY DEVICE” filed Sep. 18, 2011. Another example is described in U.S. patent Ser. No. 12/694,690 entitled “NON-VOLATILE SEMICONDUCTOR STORAGE DEVICE” filed Jan. 27, 2010. The entire contents of these patent applications are incorporated herein by reference.

The NAND flash memory is not limited to the illustrative NAND flash memory, and it may be replaced with a three dimensional stacked NAND flash memory in which a plurality of memory cells are stacked on top of each other vertically with respect to the substrate. An exemplary three dimensional stacked NAND flash memory is described in U.S. patent Ser. No. 12/407,403 entitled “THREE DIMENSIONAL STACKED NONVOLATILE SEMICONDUCTOR MEMORY” filed Mar. 19, 2009. Other examples are described in U.S. patent Ser. No. 12/406,524 entitled “THREE DIMENSIONAL STACKED NONVOLATILE SEMICONDUCTOR MEMORY” filed Mar. 18, 2009, U.S. patent Ser. No. 12/679,991 entitled “NON-VOLATILE SEMICONDUCTOR STORAGE DEVICE AND METHOD OF MANUFACTURING THE SAME” filed Mar. 25, 2010, and U.S. patent Ser. No. 12/532,030 entitled “SEMICONDUCTOR MEMORY AND METHOD FOR MANUFACTURING SAME” filed Mar. 23, 2009. The entire contents of these patent applications are incorporated herein by reference.

### [1-3] Threshold Distribution of Memory Cell Transistor

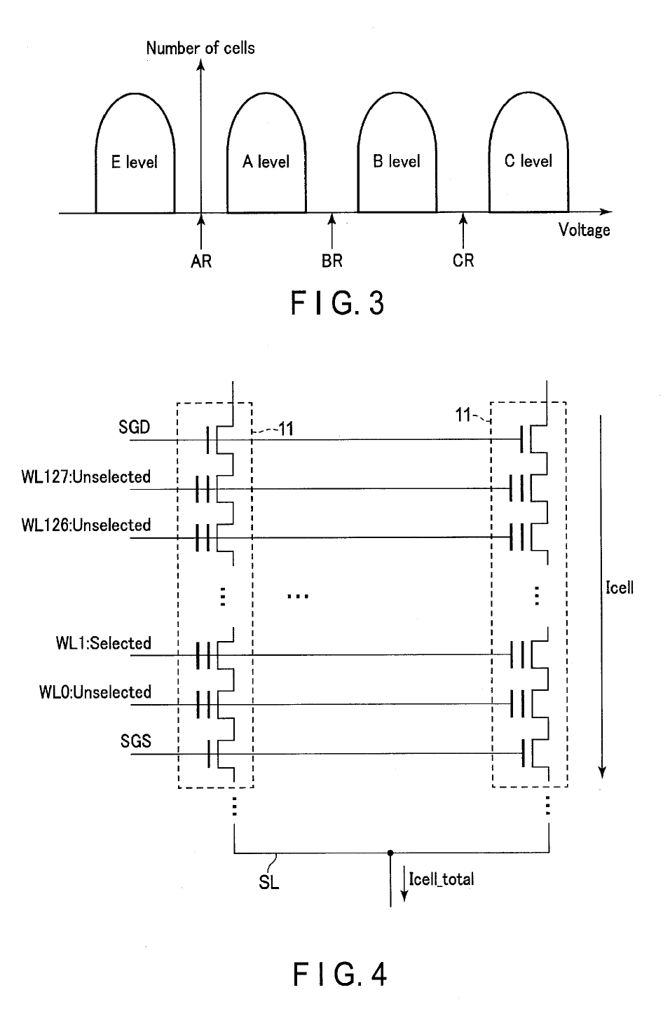

A description will be given of an exemplary threshold distribution of the memory cell transistors MT according to the first embodiment, with reference to FIG. 3.

Each memory cell transistor MT can retain, for example, 2-bit data in accordance with its thresholds. Specifically, to retain 2-bit data in the memory cell transistor MT, each memory cell transistor MT has a threshold voltage that pertains to one of four threshold distributions corresponding to four pieces of data “11”, “01”, “00”, and “10”. These four threshold distributions are defined as, for example, “E” level, “A” level, “B” level, and “C” level in increasing order of threshold.

The “E” level is a threshold distribution in the state where data has been erased. The threshold voltage of the “E” level for each memory cell transistor MT may have, for example, either a negative or positive value. The “A” to “C” levels are threshold distributions in the state where electric charge is injected into the charge storage layer of each memory cell transistor MT. The “A” level has a threshold distribution that is higher than a read voltage “AR” and lower than a read voltage “BR”. The “B” level has a threshold distribution that is higher than the read voltage “BR” and lower than a read voltage “CR”. The “C” level has a threshold distribution that is higher than the read voltage “CR”.

An exemplary NAND flash memory in this embodiment stores quaternary values; however it should be understood that it can store other multiple values, such as octal values (3 bit data) or other values.

### [1-4] Reading Operation

A description will be given of the reading operation of a NAND flash memory according to the first embodiment, with reference to FIGS. 1 to 4. The following description will be given on the assumption that data is read from the memory cell transistors MT in the block BLK0 which are connected to the word line WL1.

First, the select gate line driver 33 applies an “H” level to the select gate lines SGD and SGS through the row decoder 30, turning on the selection transistors ST1 and ST2. Then, the word line driver 32 applies a read voltage VCGRV to the selected word line WL1 through the row decoder 30. The voltage VCGRV is varied depending on data to be read. More specifically, in a normal reading operation (normal read), the word line driver 32 applies one of the read voltages “AR”, “BR”, and “CR” (second read voltage) to the selected word line WL1 as the voltage VCGRV.

Information regarding this second read voltage may be retained in a register (not illustrated) within the NAND flash memory 100. If the first read fails and then the second read (called retry read) is performed, a voltage obtained by adding a shift value to the voltage value “AR”, “BR”, or “CR” is applied to the selected word line WL as the voltage VCGRV.

The word line driver 32 applies a voltage VREAD to the non-selected word lines WL0 and WL2 to WL127 through the row decoder 30. The voltage VREAD is a voltage that turns on the memory cell transistors MT regardless of the retained data. For example, the voltage VREAD may be a voltage higher than that at the upper edge of the cell threshold distribution of the “C” level.

The above operation results in the turn-on of the memory cell transistors MT connected to the selected word line WL1, feeding cell currents Icell from the bit lines BL to the source line SL through the corresponding NAND strings 11. However, when the memory cell transistors MT connected to the selected word line WL1 are turned off, no cell current Icell flows from the bit lines BL to the source line SL through the corresponding NAND strings 11. In this way, it is possible to identify data in each memory cell transistor MT depending on whether a cell current Icell flows from the bit line BL to the source line SL.

### [1-5] First Operation

In the above reading operation, by an application of any one of the second read voltages “AR”, “BR”, and “CR” to the selected word line WL1, so that the data can be read. In some cases, however, the threshold distribution of the write cells in actual memory cell transistors MT is widened or the threshold distribution of the write cells is greatly shifted, which leads to an occurrence of a read error. Accordingly, this embodiment finds an appropriate first read voltage. This operation is referred to as a first operation.

The first operation will be described with reference to FIGS. 4 to 6. Hereinafter, this operation searches for a first read voltage for use in determining whether the memory cell transistors MT which are connected to the word line WL1 in the block BLK0 has the threshold voltage within the “A” level or the “B” level. A description will be given later of details of the timing when the first operation is performed (refer to fourth and fifth embodiments).

First, the select gate line driver 33 applies an “H” level voltage to the select gate lines SGD and SGS through the row decoder 30, turning on the selection transistors ST1 and ST2. Furthermore, the word line driver 32 applies a voltage VREAD ((e) in FIG. 6) to the non-selected word lines WL0 and WL2 to WL127 in the block BLK0 to be selected for read through the row decoder 30.

The word line driver 32 applies a voltage ((a) in FIG. 6, such as OV) to the selected word line WL1 through the row decoder 30. Then, the word line driver 32 sequentially increases the voltage applied to the word line WL1. Here, the expression “sequentially increases the voltage” means that a voltage increases in the shape of slopes or small steps on a graph indicating a voltage.

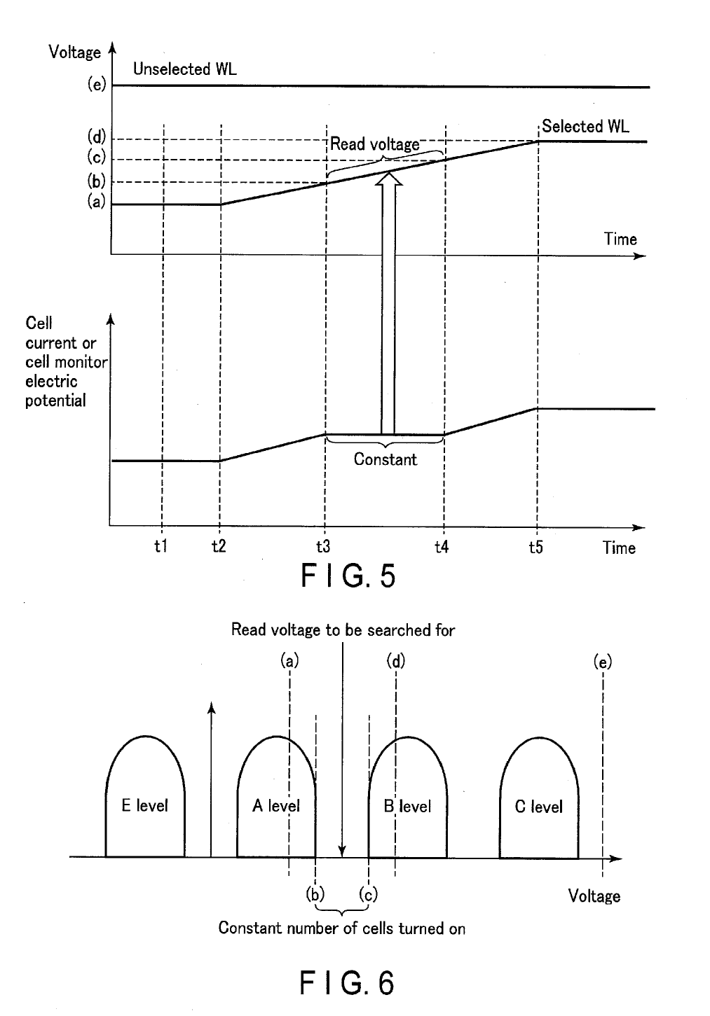

When the voltage of the selected word line WL1 is the voltage within the threshold distribution of the “A” level (from the time t2 to time t3 in FIG. 5), such as from (a) to (b) in FIG. 6, in accordance with an increase of the voltage applied to the selected word line WL1, the number of memory cell transistors MT which retain the threshold voltages lower than the voltage of the selected word line WL1 increases. In other words, depending on the increase of the voltage of the selected word line WL1, the number of memory cell transistors MT turned on increases. Consequently, the amount of the cell current Icell_total (the sum of the cell currents Icell) flowing through the memory cell transistors MT in the selected block BLK0 increases.

When the voltage of the selected word line WL1 falls within the range between the voltage (b) on the upper edge of the “A” level and the voltage (c) on the lower edge of the “B” level (from the time t3 to time t4 in FIG. 5), the number of memory cell transistors MT turned on is substantially constant. Consequently, the amount of the cell current Icell_total flowing through the memory cell transistors MT in the selected block BLK0 becomes substantially constant.

The voltage applied to the selected word line WL1 (the time t4 to time t5 in FIG. 5) is further increased, the voltage of the selected word line WL1 exceeds the voltage (c) and the number of memory cell transistors MT turned on begins to increase. Thus, the amount of the cell current Icell_total flowing through the memory cell transistors MT in the selected block BLK0 further increases.

During the first operation described above, the detecting circuit 63 in the monitor circuit 60 detects a period over which the amount of the cell current Icell_total flowing through the memory cell transistor MT in the selected block BLK0 is substantially constant.

If the difference (I2−I1) between the value I1 of the cell current Icell_total at the time t3 and the value I2 of the cell current Icell_total at the time t4 is substantially zero, the detecting circuit 63 determines that the current values I1 and I2 are substantially constant.

When the detecting circuit 63 has, for example, a clock generating circuit, the clock generating circuit generates clock signals from, for example, the time t1. Then, this clock generating circuit transmits the number of clock signals at the time t3 and the time t4 to the control circuit 80.

When the detecting circuit 63 has, for example, a timer circuit, timer circuit may start measuring the elapsed time from, for example, the time t1, and then transmits the time count values at the time t3 and the time t4 to the control circuit 80.

The control circuit 80 designates, as the first read voltage, the voltage applied to the selected word line WL1 at the time t3 or t4, based on the number of clock signals or the time count value. In this case, the first read voltage may be the average of the voltage of the selected word line WL1 at the time t3 and the voltage of the selected word line WL1 at the time t4. Thereby, the word line driver 32 applies the first read voltage determined by the control circuit 80 to the selected word line WL through the row decoder 30, performing a reading operation.

It should be noted that a determination that the cell current Icell_total is constant may include not only when the amount of the cell current Icell_total is completely constant but also when the width of the increase or the decrease of the amount of the cell current Icell_total is very small (substantially constant).

For example, the control circuit 80 may transfer DAC (a digital analog converter) value, which is used to determine the voltage applied to the selected word line WL1, to the voltage generating circuit 34 and the voltage generating circuit 34 may generate the voltage based on this DAC value. In this case, when the voltage applied to the selected word line WL1 is sequentially increased during the first operation, the control circuit 80 can transfer a DAC value when it is determined that an amount of current Icell_total is constant by the detecting circuit 63 to the voltage generating circuit 34. And then, the control circuit 80 can perform the reading operation by using the first read voltage based on this DAC value.

### [1-6] Effects

The first embodiment finds an appropriate first read voltage for memory cell transistors MT in a first operation, and performs a reading operation by using this first read voltage. More specifically, while the voltage of a selected word line WL is sequentially increasing, a monitor circuit 60 monitors a variation in a cell current Icell_total flowing through a source line SL, and detects the period over which the amount of the cell current Icell_total is substantially constant. A control circuit 80 designates, as a first read voltage, the voltage of the selected word line WL over this period, and then performs a reading operation by using this first read voltage.

Thereby, even if cell threshold distribution of the NAND flash memory 100 is widened or cell threshold distribution is greatly shifted, this embodiment can find an appropriate first read voltage for memory cell transistors MT in a NAND flash memory 100 and then perform a reading operation. This achieves a reading operation that yields a reduction in a bit error rate.

This embodiment causes a control circuit 80 in a NAND flash memory 100 to find a first read voltage for a memory cell transistor MT. Thus, the embodiment allows the NAND flash memory 100 to automatically determine a first read voltage that yields a reduction in a bit error rate, and perform a reading operation efficiently.

This embodiment uses a first read voltage found in the above manner to decrease a bit error rate in a reading operation. This can prevent an enhancement of the ECC correcting function of a controller and multiple times of modify for a read voltage in a cell threshold. Therefore, the embodiment can avoid the cost increase in a controller and/or the lowering of a performance in a reading operation.

### [2] Second Embodiment

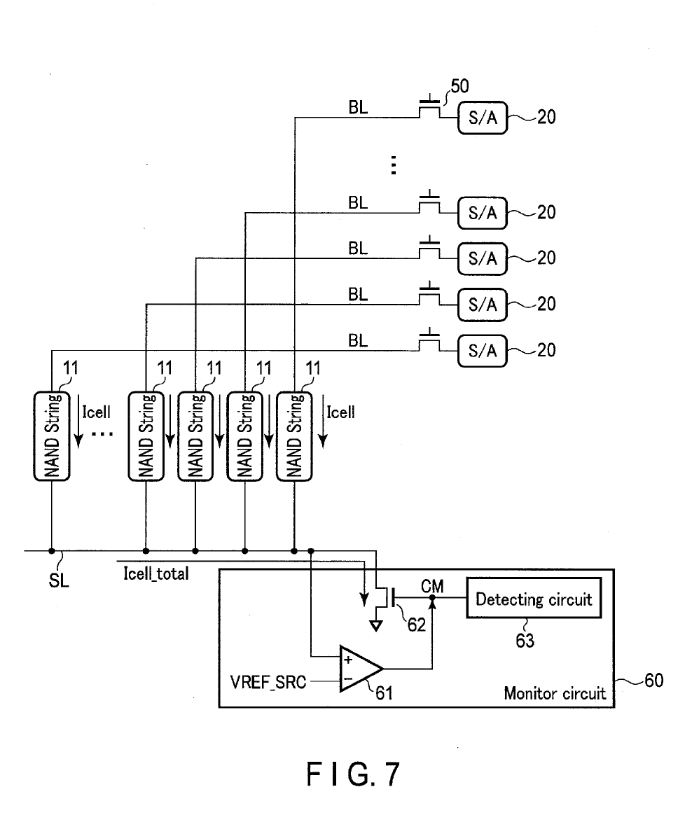

Regarding a second embodiment, a description will be given of a method of determining the constancy of a cell current Icell_total during the first operation in the first embodiment described above, with reference to FIG. 7.

In the second embodiment, a detecting circuit 63 in a monitor circuit 60 determines whether an amount of a cell current Icell_total is constant based on whether the electric potential of a cell monitor CM (the electric potential of a source line SL) is constant.

The cell current Icell_total and the electric potential of the cell monitor CM have the following relationships. As the amount of the cell current Icell_total is large, the electric potential of the cell monitor CM increases. As the amount of the cell current Icell_total is small, the electric potential of the cell monitor CM decreases. While the amount of the cell current Icell_total is constant, the electric potential of the cell monitor CM is kept constant. The detecting circuit 63 in the monitor circuit 60 accordingly measures the electric potential of the cell monitor CM and then is enable to detect a variation in the cell current Icell_total, based on the electric potential of the cell monitor CM.

### [3] Third Embodiment

To find a period over which a cell current (the electric potential of a cell monitor CM) is constant, a third embodiment finds the inflection point of a curve based on a cell current during a first operation.

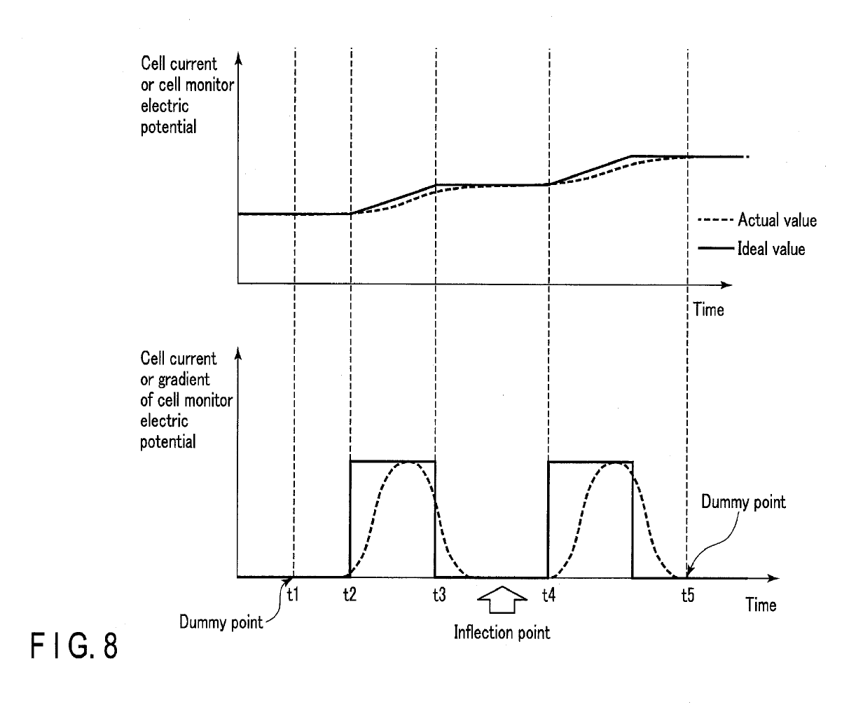

A first operation of the third embodiment will be described with reference to FIG. 8. In FIG. 8, each solid line represents an ideal value; each broken line represents an actual value. In FIG. 8, each vertical axis represents a value related to a cell current or a monitored cell electric potential, hereinafter, the cell current will be used for the explanation.

As illustrated in FIG. 8, when the voltage applied to a selected word line WL sequentially increases, an amount of a cell current flowing through the memory cell transistors MT increases or is constant because the number of memory cell transistors MT turned on by the voltage of the selected word line increases or is constant.

For example, as regards the gradient of the cell current curve of the actual values (broken line), the inflection point at which the curvature becomes 0 is present between the time t3 and the time t4. The cell current can be determined to be constant at this inflection point. A detecting circuit 63 in a monitor circuit 60 makes this determination based on the electric potential of a cell monitor CM.

Here, the term “inflection point” refers to a point on a curve in a plane at which the curved direction changes. More specifically, an inflection point is a point at which a curve changes its state from being upward convex to upward concave or from being upward concave to upward convex. One segment and other segment of a curve which are separated from each other at the inflection point are positioned on the opposite sides with respect to the straight line tangent to the curve at the inflection point. From a geometrical standpoint, an inflection point can be a point on a curve at which the sign (positive or negative) of the curvature changes.

In FIG. 8, the curvature also becomes 0 at both the time t1 and the time t5. Each of these points, however, can be regarded as a dummy point excluded from a time at which a first read voltage is to be determined, because these points are within the period over which the voltage of the selected word line WL does not change.

The third embodiment described above can use the inflection point of a cell current curve to derive more accurately a constant point of a cell current in a first operation.

The third embodiment includes, for example, a low pass filter and the like in a monitor circuit 60, may attenuate noise of a cell current by using the low pass filter. Thereby, it is possible to more accurately detect the inflection point of a cell current curve.

### [4] Fourth Embodiment

Regarding a fourth embodiment, a description will be given of a sequential flow of a reading operation including the first operation described above.

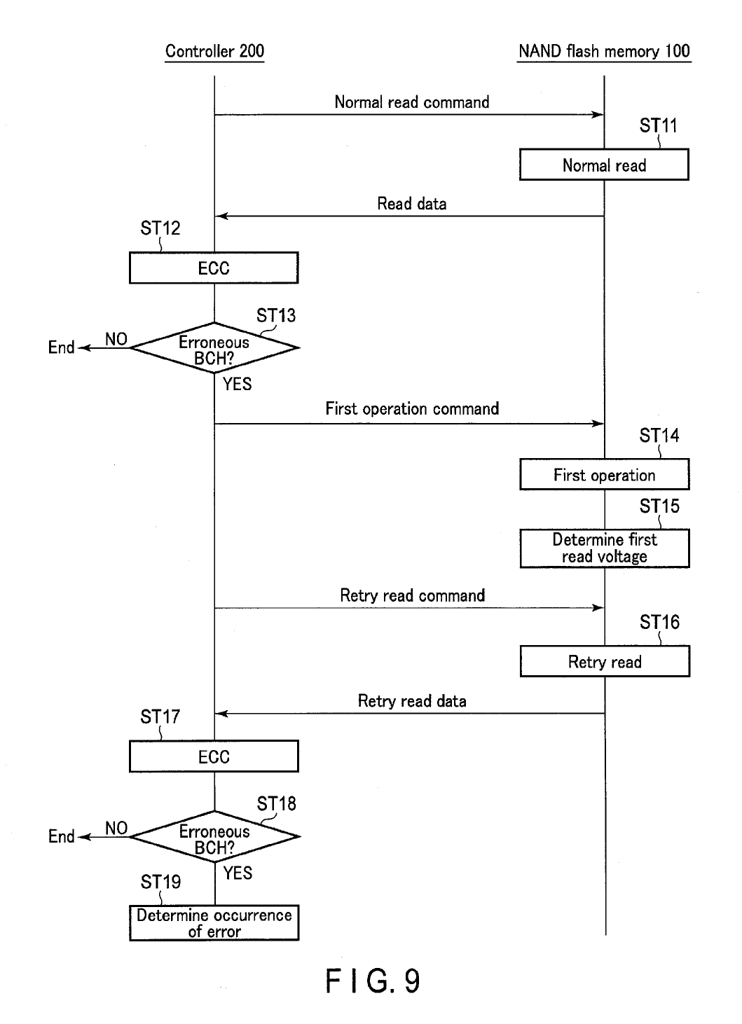

A description will be given of a sequential flow of a reading operation of a NAND flash memory according to a fourth embodiment, with reference to FIG. 9. In this embodiment, BCH (a Bose Chaudhuri Hocqenghem) code is used as an error correcting code.

First, a CPU 230 in a controller 200 issues a read command in response to an instruction from a host apparatus 300, and transmits this read command to the NAND flash memory 100. In this case, the CPU 230 also transmits block address and page address to the NAND flash memory 100. Then, in the NAND flash memory 100, normal read is performed based on the read command (ST11).

In the normal read, a second read voltage VCGRV is applied to a selected word line WL.

Read data in the normal read at Step ST11 is retained in, for example, a buffer memory 240 in the controller 200 via a NAND interface. The ECC circuit 260 in the controller 200 checks whether an error is included in the read data by using the BCH code (ST12 and ST13).

As a result, if no error is included or if the number of errors (the number of defective bits) is equal to or less than a preset number and these errors can be corrected, the operation of reading data from this page is terminated (“NO” at ST13).

If the number of errors (the number of defective bits) exceeds the preset number, the controller 200 transfers the NAND flash memory 100 to perform a first operation command. In response, the NAND flash memory 100 performs the first operation (ST14). This first operation is performed by the method described in the embodiments described above, the control circuit 80 then determines a first read voltage (ST15).

Next, the CPU 230 in the controller 200 issues a retry read command and transmits it to the NAND flash memory 100. Then, the NAND flash memory 100 performs retry read (shift read), based on the retry read command (ST16). In the retry read, the first read voltage that has been found in the first operation is applied to the selected word line WL.

The data that has been read in the retry read at Step ST16 is retained in, for example, the buffer memory 240 in the controller 200 via the NAND interface. Then, the ECC circuit 260 in the controller 200 checks whether an error is included in the read data by using the BCH code (ST17 and ST18).

As a result, if no error is included or if the number of errors (the number of defective bits) is equal to or less than the preset number and these errors can be corrected, the operation of reading data from this page is terminated (“NO” at ST18). If the number of errors (the number of defective bits) exceeds the preset number, the data is determined to be erroneous (ST19).

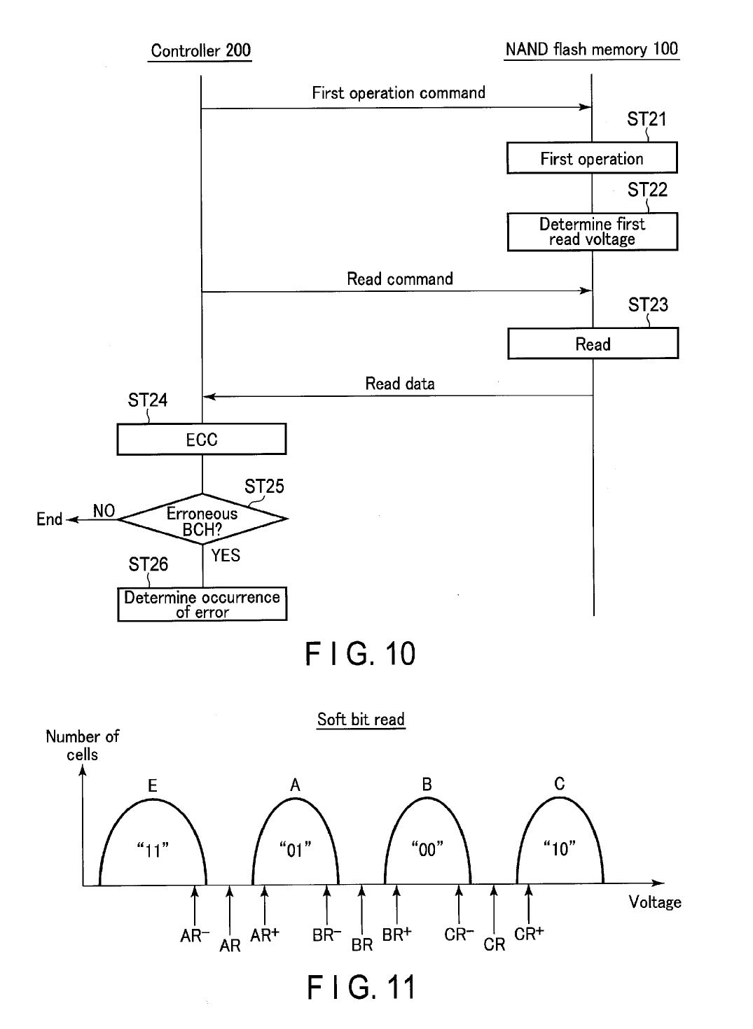

In the reading operation described above, information regarding the first read voltage that has been obtained in the first operation at Step ST14 may be retained in the controller 200 (e.g., built-in memory 220). For example, if a negatively-biased first read voltage is obtained as a result of the first operation, the lowering of the data retention characteristics is likely to occur. In this case, by giving information to the controller 200 in advance, it is possible to change the flow of the reading operation into an optimum flow of reading operation, such as performing a first operation before a reading operation (see FIG. 10). Furthermore, in such a case, thresholds of the memory cell transistors MT for pages other than the page from which the data has been read are also likely to be lowered. For this reason, in the following reading operation, data may be read while the read voltage is kept low from the beginning.

In the exemplary case illustrated in FIG. 10, because the first operation is inevitably performed, the time required to perform the series of processes in the reading operation can be made constant.

### [5] Fifth Embodiment

Regarding a fifth embodiment, a description will be given of a sequential flow of a reading operation including the first operation described above different from that of the fourth embodiment. Specifically, an LDPC (low density parity check) code is used as an error correcting code.

### [5-1] Soft Bit Read

In a NAND flash memory, distances between threshold distributions become narrow with the scale-down of elements. This trend may cause wrong data to be read during a data reading operation, leading to lowered data reliability. This embodiment accordingly uses an ECC having a high correcting capability, such as LDPC. ECCs including the LDPC and the like require values read at normal read voltages as well as another piece of threshold voltage information (called soft values). For this reason, a reading operation (soft bit read) is performed at voltages different from normal read voltages, and these results are set as soft values to be used for ECC such as LDPC.

Referring to the threshold distributions in FIG. 3, “AR”, “BR”, and “CR” correspond to the normal read voltages. The threshold voltage information is information that indicates at which location the threshold voltage of the memory cell transistor MT is positioned in one of the “E”, “A”, “B”, and “C” levels (e.g., the threshold voltage is positioned at the center or on the right or left side of the threshold distribution of the “A” level). In other words, the threshold voltage information is information that indicates the “likelihood” of read data.

Reading of the threshold voltage information described above is referred to as “soft bit read”. In contrast, reading of the normal data (“11”, “01”, “00”, or “10”) is referred to as “hard bit read”.

In the reading operation of this embodiment, in order to perform the soft bit read through which the threshold voltage information is read, voltages AR, BR, and CR as well as AR−, AR+, BR−, BR+, CR−, and CR+ are applied to a selected word line WL, as illustrated in FIG. 11. The data read at these voltages corresponds to the above threshold voltage information.

The voltage AR− is a voltage lower than the voltage AR by a preset value. The voltage AR+ is a voltage higher than the voltage AR by a preset value. The voltage BR− is a voltage lower than the voltage BR by a preset value. The voltage BR+ is a voltage higher than the voltage BR by a preset value. The voltage CR− is a voltage lower by a preset value than the voltage CR. The voltage CR+ is a voltage higher than the voltage CR by a preset value. These preset values for the voltage AR−, AR+, BR−, BR+, CR−, and CR+ may be identical to or different from one another. Each of the individual preset values may be fixed in advance or variable.

### [5-2] Read Flow

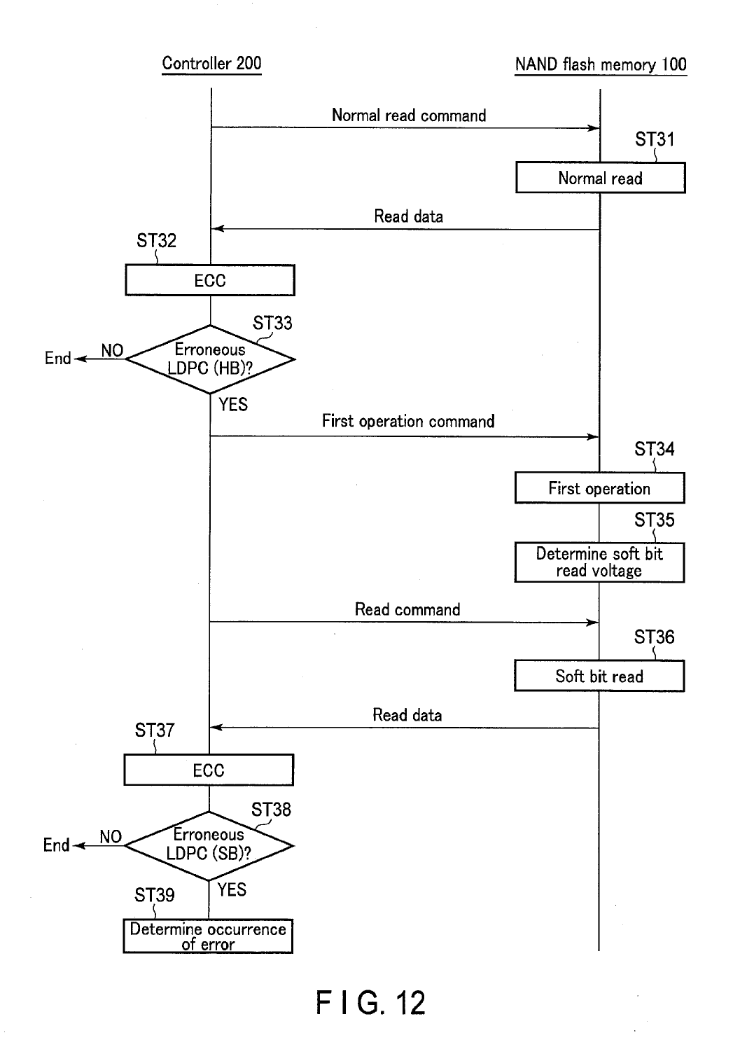

A description will be given of a sequential flow of a reading operation of a NAND flash memory according to the fifth embodiment, with reference to FIG. 12. The following description focuses on steps different from those of the fourth embodiment.

Unlike the fourth embodiment, the fifth embodiment uses first read voltages found in a first operation, as reference voltage values (AR′, BR′, and CR′) for the soft bit read (ST35).

That is, during the soft bit read at Step ST35, voltages based on first read voltages found in a first operation are applied to a selected word line WL. These voltages include the referential voltage values AR′, BR′, and CR′ as well as the voltages AR′−, AR′+, BR′−, BR′+, CR′−, and CR′+. The voltages AR′− and AR′+ are ± voltages set using AR′ as a reference, the voltages BR′− and BR′+ are ± voltages set using BR′ as a reference and the voltages CR′− and CR′+ are ± voltages set using CR′ as a reference.

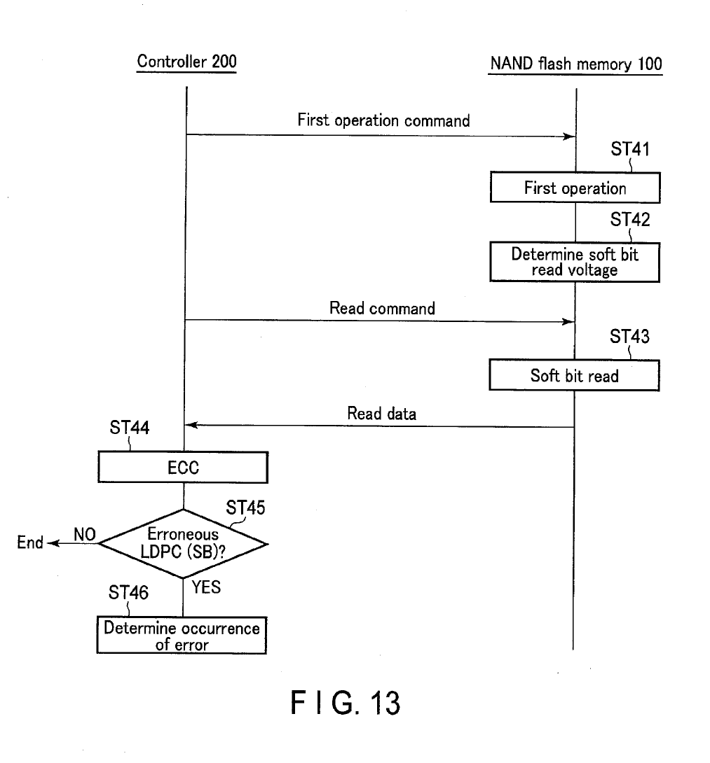

As illustrated in FIG. 13, the first operation may be performed at first. The example of FIG. 13 described above can thus ensure consistency in the time required to perform the series of processes in the reading operation.

The fifth embodiment described above can improve the correcting efficiency of a soft bit read by using first read voltages determined in a first operation.

### [6] Sixth Embodiment

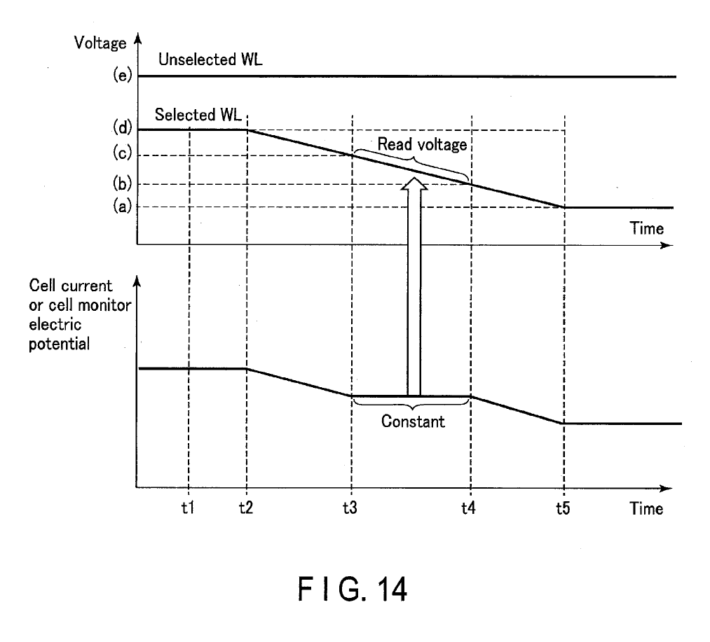

The first embodiment and others sequentially increase a voltage applied to a selected word line WL in a first operation. In contrast, a sixth embodiment sequentially decreases a voltage applied to a selected word line WL. A description will be given of steps different from those of the first embodiment, with reference to FIGS. 6 and 14.

First, a voltage (e) is applied to non-selected word lines WL0 and WL2 to WL127. In addition, a voltage (d) is applied to a selected word line WL1, and then the voltage is sequentially decreased.

From the time t2 to time t3 and from the time t4 to time t5 in FIG. 14, in accordance with the decreasing electric potential applied to the selected word line WL1, the number of memory cell transistors MT turned on by the electric potential of the selected word line WL1 decreases. In response, an amount of the cell current Icell_total flowing through the memory cell transistors MT in a selected block BLK0 decreases. From the time t3 to time t4 in FIG. 14, the number of memory cell transistors MT turned on is a substantially constant, and an amount of a cell current Icell_total flowing through the memory cell transistors MT in the selected block BLK0 is substantially constant.

The sixth embodiment described above sequentially decreases a voltage of a selected word line WL1 in a first operation, and can thereby find a first read voltage, similarly to the foregoing embodiments.

### [7] Seventh Embodiment

A seventh embodiment locks out the bit line corresponding to a memory cell transistor MT for which data has been identified, in a reading operation.

The term “lock out” refers to the operation of setting the bit line BL and source line SL of a designated memory cell transistor MT to the same electric potential (e.g., 0 V) and not charging this bit line BL.

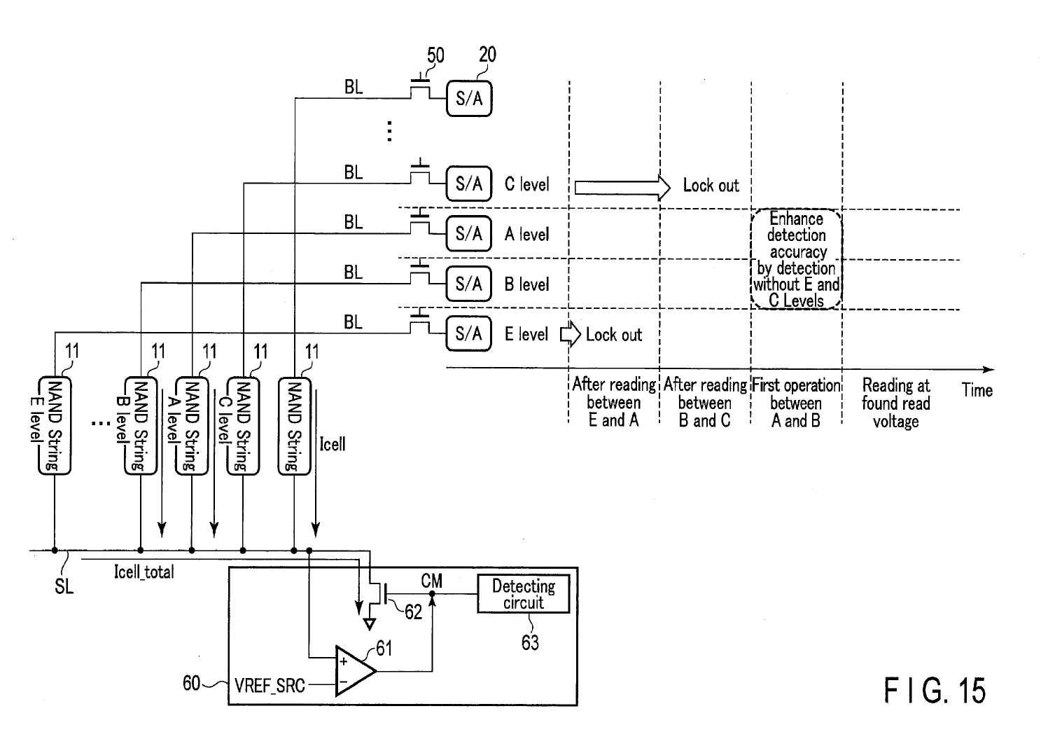

A description will be given of a reading operation including a first operation according to a seventh embodiment, with reference to FIG. 15. In this description, the seventh embodiment searches for a first read voltage between an “A” level and a “B” level in a first operation.

First, a read voltage “AR”, which is between an “E” level and an “A” level, is applied to a selected word line WL. If it is determined that the threshold of the selected cell falls within the “E” level, the bit line BL connected to the selected cell in the turn-on state is locked out.

Next, a read voltage “CR”, which is between the “B” level and a “C” level, is applied to a selected word line WL. If it is determines that the threshold of the selected cell falls within the “C” level, the bit line BL corresponding to this is locked out.

Thus, while the bit lines BL corresponding to the cells of the “E” level and the “C” level are kept locked out, a first read voltage between the “A” level and “B” level is searched. In this time, no cell currents Icell flow through the NAND strings 11 in which the cells of the “E” level and the “C” level are present. This prevents the cell current Icell_total during the first operation from being affected by the cell currents Icell based on the cells of the “E” level and the “C” level. The seventh embodiment described above locks out the bit line BL corresponding to a memory cell transistor MT for which the level of the cell threshold distribution has been identified in a reading operation, and then performs a first operation. In this case, a cell current Icell does not flow from the bit line BL that has been locked out to a source line SL, whereas a cell current Icell flows from a bit line BL that is not locked out to the source line SL. This prevents the detection of a cell current Icell_total during a first operation from being affected by a memory cell transistor MT for which the level of the cell threshold distribution has been identified. Consequently, it is possible to detect more accurately the period over which an amount of a cell current Icell_total is kept constant (the monitored cell electric potential is kept constant), finding a first read voltage precisely.

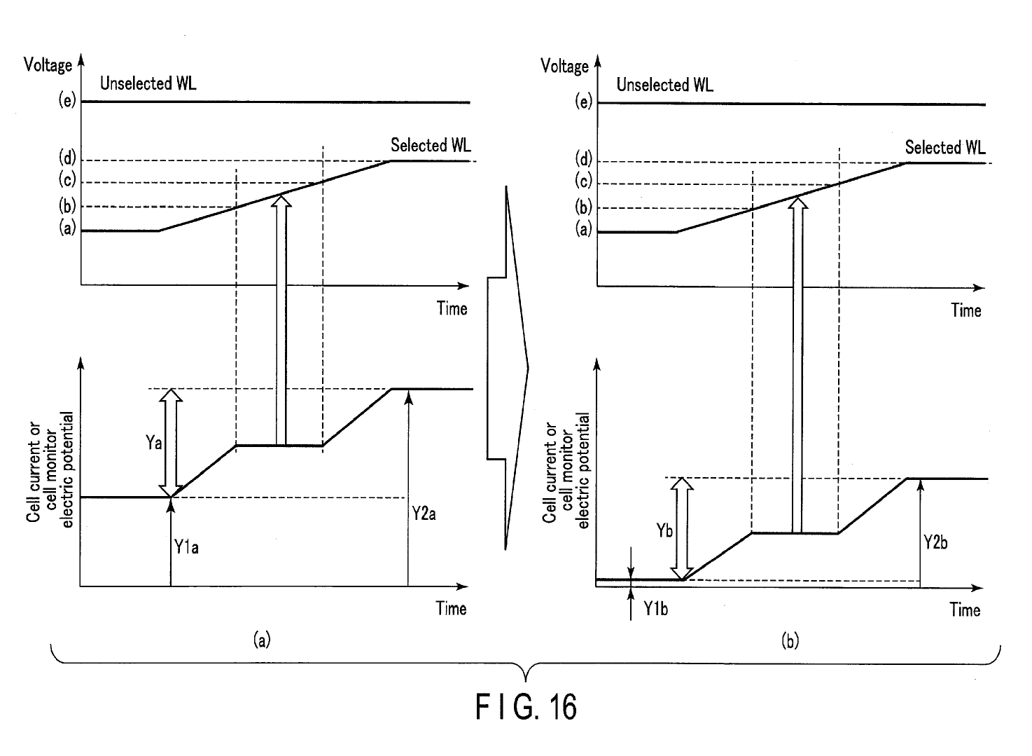

Referring to (a) of FIG. 16 illustrating an example in which lockout is not performed and (b) of FIG. 16 illustrating an example in which lockout is performed (seventh embodiment), cell currents Icell_total (both monitored cell electric potentials) in a first operation are compared. In this case, the respective differences Ya and Yb between the maximum values and minimum values of both the cell currents Icell_total are equal to each other. However, the minimum value Y1b of the cell current Icell_total is lower than the minimum value Y1a; the maximum value Y2b of the cell current Icell_total is lower than the maximum value Y2a. Accordingly, Yb/Y1b and Yb/Y2b are greater than Ya/Y1a and Ya/Y2a. The seventh embodiment thus increases the ratio of the difference to the absolute value of the cell current Icell_total, making it possible to detect the cell current Icell_total with improved precision.

### [8] Eighth Embodiment

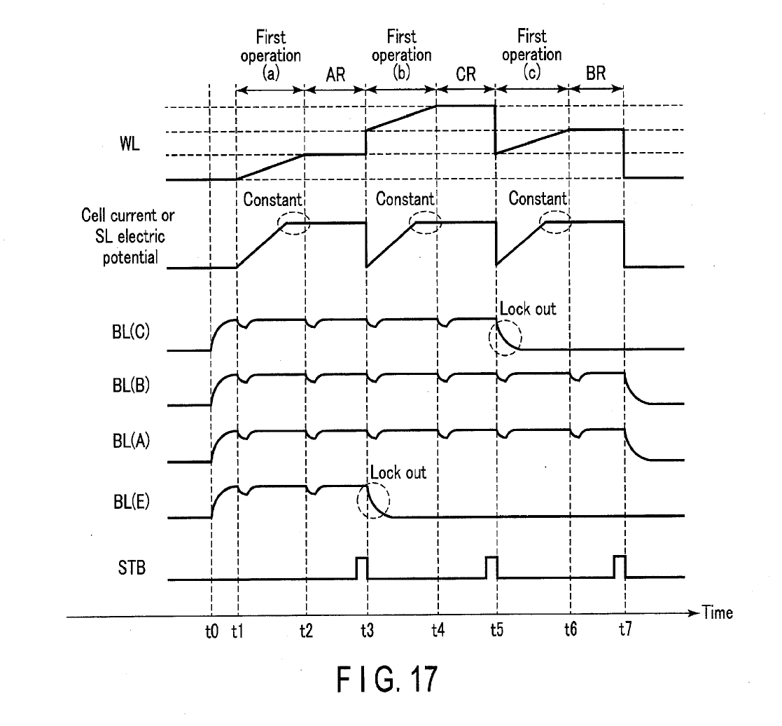

Regarding an eighth embodiment, a description will be given of a timing of a first operation as described in the above embodiments, with reference to FIG. 17. Here, the embodiment performs the first operation (a) to find a first read voltage between an “E” level and an “A” level, the first operation (b) to find a first read voltage between a “B” level and a “C” level and the first operation (c) to find a first read voltage between the “A” level and a “B” level.

From the time t1 to time t2, the first operation (a) is performed. More specifically, the voltage applied to a selected word line WL is sequentially increased, and a variation in the cell current in the meantime is detected. As a result, the voltage of the selected word line WL during the period over which the cell current is kept substantially constant is determined to be a first read voltage between the “E” level and the “A” level.

From the time t2 to time t3, the first read voltage determined in the first operation (a) is applied to the selected word line WL. In addition, a voltage VREAD is applied to the non-selected word lines WL. As a result, when the memory cell transistor MT connected to the selected word line WL turns on, a current flows from the bit line BL to the source line SL through the corresponding NAND string 11. The threshold of the memory cell transistor MT turned on in this reading operation can be determined to be the “E” level. An STB signal is set to an “H” level, and the data for this bit line BL undergoes strobe.

At the time t3, the bit line BL corresponding to the memory cell transistor MT determined to be the “E” level is locked out. The remaining bit lines BL that are not locked out are continuously pre-charged.

From the time t3 to time t4, the first operation (b) is performed. More specifically, the voltage of a selected word line WL is sequentially increased, and a variation in the cell current is detected in the meantime. As a result, the voltage of the selected word line WL during the period over which the amount of the cell current is kept substantially constant is determined to be a first read voltage between the “B” level and the “C” level.

From the time t4 to time 5, a reading operation is performed by the first read voltage determined in the first operation (b). More specifically, the first read voltage is applied to the selected word line WL. In addition, the voltage VREAD is applied to the non-selected word lines WL. As a result, when the memory cell transistor MT connected to the selected word line WL turns on, and a current flows from the bit line BL to the source line SL through the corresponding NAND string 11. The threshold of the memory cell transistor MT that has not been turned on in this reading operation can be determined to be the “C” level. An STB signal is set to an “H” level, and the data for this bit line BL undergoes strobe.

At the time t5, the bit line BL corresponding to the memory cell transistor MT determined to be the “C” level is the locked out. The remaining bit lines BL that are not locked out are continuously pre-charges.

From the time t5 to time t6, the first operation (c) is performed. As a result, the voltage of a selected word line WL during a period over which the cell current is kept constant is determined to be a first read voltage between the “A” level and the “B” level.

From the time t6 to time t7, a reading operation is performed by the first read voltage determined in the first operation (c). More specifically, the first read voltage is applied to the selected word line WL. In addition, the voltage VREAD is applied to the non-selected word lines WL. As a result, when the memory cell transistor MT connected to the selected word line WL turns on, a current flows from the bit line BL to the source line SL through the corresponding NAND string 11. And also, in this reading operation, the threshold of the memory cell transistor MT turned on can be determined to be the “A” level and the threshold of the memory cell transistor MT that has not been turned on can be determined to be the “B” level.

The eighth embodiment described above determines first read voltages in first operations (a) to (c), and then performs reading operations at these voltages. More specifically, after the first operation is performed, the eighth embodiment performs a reading operation while maintaining the found first read voltage.

The first operations do not necessarily have to be performed at the timing illustrated in FIG. 17. For example, the first operations (a) to (c) may be successively performed before a reading operation starts. In this case, the found first read voltages may be retained on a side of the controller 200.

### [9] Ninth Embodiment

The embodiments described above detect the period over which the electric potential (cell current) of a source line SL is kept constant during a first operation. In contrast, a ninth embodiment detects the period over which an electric potential VDD of an interconnect of a VDD monitor circuit is kept constant.

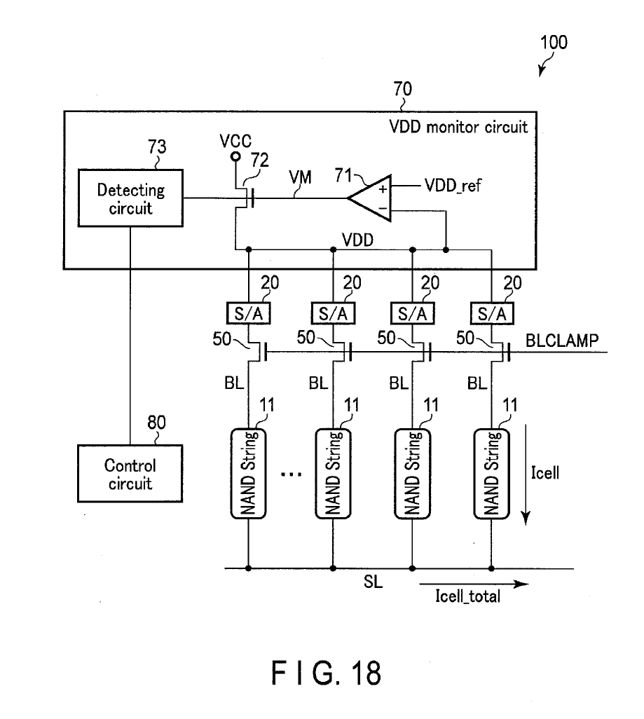

As illustrated in FIG. 18, a NAND flash memory 100 in the ninth embodiment includes a VDD monitor circuit 70. This VDD monitor circuit 70 includes: a feedback circuit having a comparator 71 and a MOS transistor 72; and a detecting circuit 73.

The comparator 71 includes an inverting input terminal (−) and a non-inverting input terminal (+). The inverting input terminal (−) of the comparator 71 is connected to bit lines BL and a referential electric potential VDD_ref is supplied to the non-inverting input terminal (+) of the comparator 71. The comparator 71 compares the electric potential VDD of the interconnect of the VDD monitor circuit 70 with the referential electric potential VDD_ref. Then, both the comparator 71 and the MOS transistor 72 cooperate in such a way that the electric potential VDD becomes equal to the referential electric potential VDD_ref.

The MOS transistor 72 includes a current path and a gate. One end of the current path of the MOS transistor 72 is connected to a power supply terminal VCC and the other end of the current path of the MOS transistor 72 is connected to the bit lines BL. The gate (VDD monitor VM) of the MOS transistor 72 receives an electric potential based on a comparison result of the comparator 71.

The detecting circuit 73 is connected to the gate of the MOS transistor 72. This detecting circuit 73 detects the period over which the electric potential (electric potential VDD) of the VDD monitor VM is kept substantially constant during a first operation as described above. The detecting circuit 73 operates in the same manner as in the detecting circuit 63. A control circuit 80 determines the first read voltage for memory cell transistor MT, based on information (e.g., the number of clock signals and/or time count value) regarding the period detected by the detecting circuit 73.

In the ninth embodiment, the electric potential of a selected word line WL is sequentially increased during a first operation, the number of memory cell transistors MT turned on by the potential of the selected word line WL, as the increasing electric potential applied to the selected word line WL, increases or is constant. In response, an amount of the cell current Icell_total flowing through the memory cell transistors MT in the selected block BLK increases or is constant. In this case, the monitor circuit 70 monitors a variation in the electric potential of the VDD monitor VM which is caused due to a variation in the cell current Icell_total.

Here, the cell current Icell_total and the electric potential of the VDD monitor VM establish the following relationships. When the amount of the cell current Icell_total is large, the electric potential of the VDD monitor VM increases. When the amount of the cell current Icell_total is small, the electric potential of the VDD monitor VM decreases. While the amount of the cell current Icell_total is constant, the electric potential of the VDD monitor VM is kept constant. These relationships enable the monitor circuit 70 to measure the electric potential of the VDD monitor VM and to detect a variation in cell current Icell_total from the variation in the electric potential of the VDD monitor VM.

As a result, the control circuit 80 designates, as a first read voltage, the voltage applied to the selected word line WL during the period over which the electric potential (electric potential VDD) of the VDD monitor VM is kept constant. Then, it is possible to achieve a reading operation that yields a reduction in a bit error rate by performing a reading operation by using this first read voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
memory cells;
word lines electrically connected to gates of the memory cells; and
an interconnect electrically connected to one end of the memory cells,
wherein a first potential for applying to a selected memory cell in a read operation is determined based on a potential of the interconnect during sequentially increasing or decreasing a potential of the word line.

2. The device according to claim 1, wherein
the first potential is the potential of the word line when the potential of the interconnect becomes substantially constant.

3. The device according to claim 1, wherein
The first potential is the potential of the word line when a curve based on a variation in the potential of the interconnect indicates an inflection point.

4. The device according to claim 1, further comprising a monitor circuit electrically connected to the interconnect,
the monitor circuit including:
a comparator to compare the potential of the interconnect with a referential potential;
a transistor, one end of the transistor electrically being connected to the interconnect and a gate of the transistor being connected to the comparator; and
a detecting circuit to detect a potential of the gate of the transistor during sequentially increasing or decreasing the potential of the word line.

5. The device according to claim 1, wherein
the interconnect is a source line.

6. The device according to claim 1, wherein
the interconnect is a bit line.

7. The device according to claim 1, wherein
the first potential is determined after the potential of the interconnect at one end of a memory cell whose a threshold is identified among the memory cells becomes equal to that of another interconnect at the other end of the memory cell whose the threshold is identified.

8. A semiconductor memory device comprising:
memory cells;
word lines electrically connected to gates of the memory cell; and
an interconnect electrically connected to one end of the memory cells,
wherein a first potential for applying to a selected memory cell in a read operation is determined based on a current of the interconnect during sequentially increasing or decreasing a potential of the word line.

9. The device according to claim 8, wherein
the first potential is the potential of the word line when the current of the interconnect becomes substantially constant.

10. The device according to claim 8, wherein
The first potential is the potential of the word line when a curve based on a variation in the current of the interconnect indicates an inflection point.

11. The device according to claim 8, further comprising a monitor circuit electrically connected to the interconnect,
the monitor circuit including:
a comparator to compare the current of the interconnect with a referential current;
a transistor, one end of the transistor electrically being connected to the interconnect and a gate of the transistor being connected to the comparator; and
a detecting circuit to detect a potential of the gate of the transistor during sequentially increasing or decreasing the potential of the word line.

12. The device according to claim 8, wherein
the interconnect is a source line.

13. The device according to claim 8, wherein
the interconnect is a bit line.

14. The device according to claim 8, wherein
the first potential is determined after the potential of the interconnect at one end of a memory cell whose a threshold is identified among the memory cells becomes equal to that of another interconnect at the other end of the memory cell whose the threshold is identified.

15. A memory system comprising:
a memory device including memory cells, word lines electrically connected to gates of the memory cells, and an interconnect electrically connected to one end of the memory cells; and
a controller configured to control a read operation of the memory device,
wherein a first potential for applying to a selected memory cell in the read operation is determined based on a potential of the interconnect during sequentially increasing or decreasing a potential of the word line.

16. The system according to claim 15, wherein
the first potential is the potential of the word line when the potential of the interconnect becomes substantially constant.

17. The system according to claim 15, wherein
the first potential is the potential of the word line when a curve based on a variation in the potential of the interconnect indicates an inflection point.

18. The system according to claim 15, wherein
the memory device further includes a monitor circuit electrically connected to the interconnect,
the monitor circuit includes:
a comparator to compare the potential of the interconnect with a referential potential;
a transistor, one end of the transistor electrically being connected to the interconnect and a gate of the transistor being connected to the comparator; and
a detecting circuit to detect a potential of the gate of the transistor during sequentially increasing or decreasing the potential of the word line.

19. The system according to claim 15, wherein
the interconnect is one of a source line and a bit line.

20. The system according to claim 15, wherein
the first potential is determined after the potential of the interconnect at one end of a memory cell whose a threshold is identified among the memory cells becomes equal to that of another interconnect at the other end of the memory cell whose the threshold is identified.
